(19) United States
(12) Patent Application Publication
(10) Pub. No.: US 2003/0234394 A1
(43) Pub. Date: Dec. 25, 2003

(54) Measuring force on dies and substrates

(76) Inventors: Rafiqul Hussain, Fremont, CA (US); Richard Block, Daly City, CA (US)

Correspondence Address: FARJAMI & FARJAMI LLP, 16148 SAND CANYON, IRVINE, CA, 92618, US

(21) Appl. No.: 10/180,856

(22) Filed: Jun. 25, 2002

(51) Int. Cl. H01L 21/66; G01R 31/26; H01L 23/58; H01L 21/44; H01L 21/48; H01L 21/50

(52) U.S. Cl. 257/48; 438/14; 438/15

(57) ABSTRACT

Systems and methods of measuring force on dies and substrates are provided. In one system, a force measurement die is substituted for a die to be tested on a substrate.

### BACKGROUND

1. Field of the Invention

The present invention relates to testing circuits, and specifically to measuring force applied to dies and substrates.

2. Description of the Related Art

Dies and substrates placed on sockets, which are placed on a circuit board, may be tested once force measured is confirmed and verified to be within a specification.

### SUMMARY

In a test environment, a test is performed with a die/substrate on automated handlers connected to a test system. In a System Level Test (SLT) environment the die/substrate is tested semi-manually on a printed circuit mother board with a thermal head applying pressure on the die and substrate.

A die comprises a silicon material, which is sensitive, and also has solder bumps below the die, which are force sensitive. Force on a substrate is also critical because new packages come in either organic and ceramic substrates and require difference force due to warpage, thickness, and solder connect between die and substrate.

During testing of a die and/or a substrate on a socket in either a test environment or a System Level Test (SLT) environment, it is important to know the proper amount of force in providing the proper conditions for temperature and electrical conductivity. A thermal interface material between the die and a heat sink allows for heat transfer from die to the heat sink as such material used could either be a thermal grease or a carbon-based thermally conductive material. Applying optimum force and achieving test performance standards in a production setup is desired. With pin lengths and ball diameters for BGA substrates shrinking along with thinner organic substrates across all types of devices, less force is desired. This desire is amplified when BI-32 or BI-64 are used in memory chips, where 32 dies or 64 devices are tested simultaneously (in parallel). In the case of a memory chip testing, 32 devices may be tested in parallel on a handler. The setup may have 1, 8, 16 32 or 64 devices being tested at a time.

In accordance with the present invention, a system and method of measuring force on dies and substrates are provided. One embodiment of the invention relates to a system of measuring force on a package comprising a lid, a die and a substrate. The die comprises a transducer.

Processors and chip set products may have lids on top of the die for thermal and mechanical needs. In order to test the integrated circuits (ICs), i.e., the dies on a substrate, force needs to be applied on the lid such that the die sees a certain amount of pressure, which can be critical to performance and mechanical integrity. The die may require certain force for thermal interface material in forming processors. Also, it may be critical that minimum force be applied on the die due to warpage issues and C4 bumps below the die.

When testing a die on a substrate in a tester/handler configuration, the force is applied from the top. Similarly, when testing a die or package in a system level test (SLT) environment, force is applied from the top by thermal heads that come down on the package. In both cases, the force on a die or package/substrate may be very critical to define and use in production.

In another embodiment, a system measures force on a die on a substrate without a lid. The die comprises a transducer.

In a test environment, applying minimum force on a die and/or a substrate may be preferred. Too much force applied on a die and/or a substrate can lead to pin bends, ball deformation, die chippage and package cracking, which may increase the costs of maintenance and repair.

In another embodiment, a system measures force on a die on a modified thin substrate. The die comprises a transducer.

A force applied on substrates on a production setup may involve hard stops, which relate to a pre-defined travel of socket pins to make good electrical contacts. A hard stop provides an external mechanical limit (a hard stop is a maximum limit beyond which force will not travel onto the die and/or substrate) and is not very effective in determining an actual force applied during test in a manufacturing environment. The system of measuring force on a die on a modified thinner substrate is able to predefine the actual force needed for precise electrical contacts as well as optimum thermal performance. Certain thermal interface materials placed on top of the die for heat transfer require specific force per size of die and/or substrate because determining what is being applied is useful and critical.

The systems herein will advantageously help ensure that proper settings for testing are used and maintained across test systems. The system may improve reliability, improve precision in thermal performance, improve accuracy, reduce cost of manufacturing, simplify manufacturing and improve wear characteristic. The system may be used to test microprocessors based upon measured force on the die/substrate.

One aspect of the invention relates to a test package comprising a transducer configured to measure an amount of force applied to the transducer. The transducer is attached to a support structure, which is attached to a substrate. The transducer is shaped and sized to emulate a die to be tested.

Another aspect of the invention relates to a system configured to measure force applied to a device. The system comprises a means for applying a downward force on a device; and a device comprising a transducer configured to measure an amount of force applied by the force applying means to the device. The transducer is attached to a support structure, which is attached to a substrate. The transducer is shaped to emulate a die.

Another aspect of the invention relates to a test package comprising a transducer configured to measure an amount of force applied to the transducer. The transducer is attached to a force measurement package, which is attached to a substrate. The transducer is shaped and sized to emulate a die to be tested.

Another aspect of the invention relates to a method of testing a device, the method comprising: measuring an amount of force applied to a transducer that is shaped and sized to emulate a die on a substrate; verifying an amount of desired force for optimal thermal performance and a socket-per-pin force specification; and setting the verified amount of force to be used in a die and substrate production process.

### BRIEF DESCRIPTION OF THE DRAWINGS

FIG. 1 illustrates one embodiment of a system configured to measure force applied to a substrate with a lid.

FIG. 2 illustrates one embodiment of a system configured to measure force applied to a force measurement die in a test environment.

FIG. 3 illustrates one embodiment of a system configured to measure force applied to a force measurement die or device die on a force measurement package 304 and a modified thin substrate.

### DETAILED DESCRIPTION

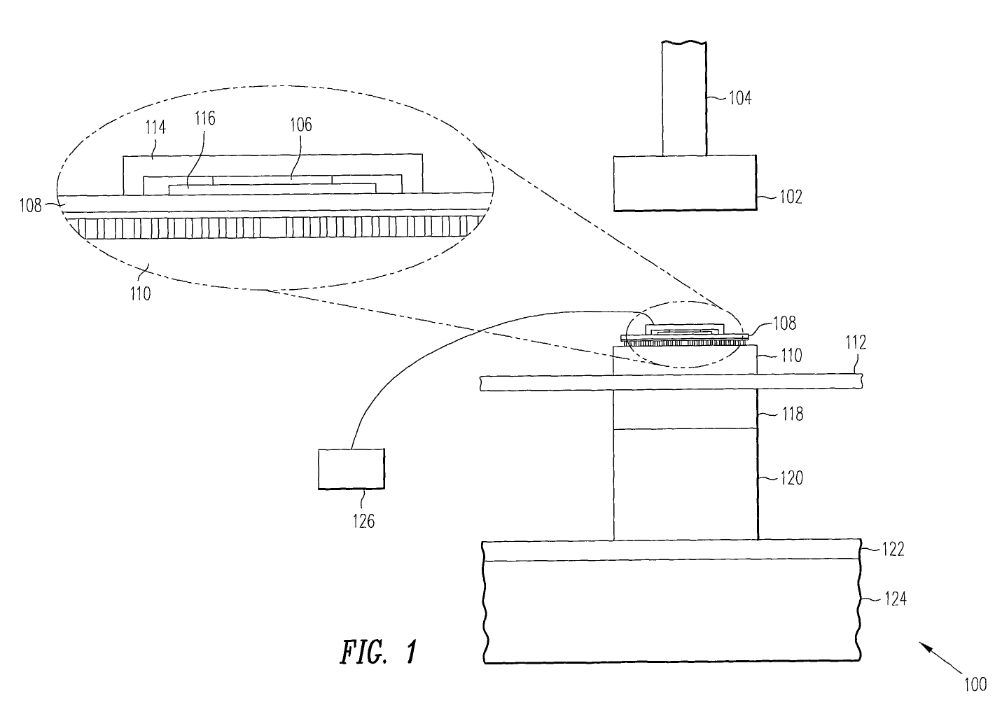

FIG. 1 illustrates one embodiment of a system 100 configured to measure force applied to a substrate 108 with a lid 114. The system 100 comprises a thermal head 102, a shaft 104, a force measurement die 106, a substrate 108, a socket 110, a printed circuit board 112, a lid 114, a support structure 116, a plastic insulator 118, another support structure 120, a sub-plate 122 and a base plate 124. The system 100 may comprise other components in addition to or instead of the components shown in FIG. 1.

The substrate 108 may be organic or ceramic. The support structure 120, sub-plate 122 and base plate 124 may be made of aluminum or some other suitable material.

In one embodiment, a standard “package” (not shown) may comprise a substrate, a die and a lid. A standard package may have either a ceramic or organic substrate, which may contain either pins or solder balls. The silicon die is placed on top of the substrate using C4 solder bumps for interconnects between the silicon die and the substrate. The package may further comprise a support structure between the die and the substrate. The die may comprise a chip set, a processor or some other integrated circuit.

To determine the force being exerted on a package (lid, die and substrate), a force measurement die 106 in FIG. 1 is substituted in place of a die and integrated inside and below the lid 114 to emulate a die in a standard package. The force measurement die 106 comprises a transducer. The force measurement die 106 is preferably shaped with exactly the same dimension and size as a die to be emulated. In one embodiment, the force measurement die 106 is placed and attached (e.g., glued) onto a support structure 116, which is placed and attached (e.g., glued) onto the substrate 108. Like a real package, the substrate 108 is placed on the test socket 110.

A force is applied to test the package either on a Tester setup or a System Level Test (SLT) setup. A Tester is usually connected to a Test Handler and is considered a Test System setup, whereas a System Level Test configuration involves substrates placed on printed circuit boards (also called mother boards) and compressed with the die/substrate. The force measurement die 106 may be coupled to a display 126 or some other device configured to show an amount of measured force to a user.

First, an actual force is verified and confirmed for optimal thermal performance and to meet the parameters of the thermal interface material and socket per pin force. Then the pressure applied using the thermal head 102 is set in production with the proper pressure for the specific force needed (pressure applied is either air-based or could be just physical force per measured area) and thermal head performance for maintaining precise temperature set points for testing units.

In one embodiment, the pressure applied to a die in a standard package should be much lower than the pressure applied to the substrate because of the sensitivity of the silicon and C4 solder bumps on the die. Knowing the force on the die based on a specification (solder balls for C4 bumps or just solder balls on BGA substrates; solder balls are of certain composition of tin/lead, and in the future it could be of tin/silver/other), one can determine exactly how much force is being applied on the die and on the package using the system 100 of FIG. 1.

The system 100 may be specifically designed or adapted to precisely measure a desired force on die and/or package to be tested, such as Ball Grid Arrays, Land Grid Arrays, Micro Organic Pin Grid Arrays and Std Pin Grid Arrays (longer pin grid arrays) for both ceramic and organic substrates. Different dies and packages have different sizes and dimensions. In order to adapt this measuring technique for various substrates, a customized system may be set up for each of these specific substrate configurations.

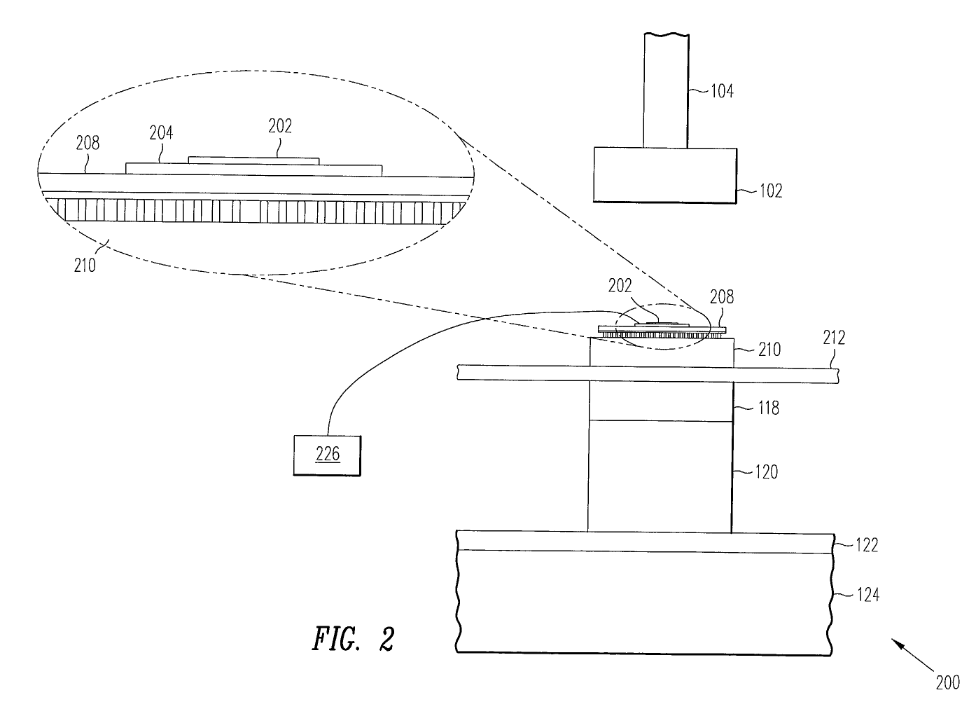

FIG. 2 illustrates one embodiment of a system 200 configured to measure force applied to a force measurement die 202 in a test environment. The system 200 comprises a thermal head 102, a shaft 104, a force measurement die 202, a support structure 204, a substrate 208, a socket 210, a printed circuit board 212, a plastic insulator 118, another support structure 120, a sub-plate 122 and a base plate 124. The system 200 may comprise other components in addition to or instead of the components shown in FIG. 2.

The substrate 208 in FIG. 2 may be organic or ceramic. The support structure 120, sub-plate 122 and base plate 124 may be made of aluminum or some other suitable material.

In one embodiment, a standard “package” (not shown) may comprise a die on a substrate. The package may further comprise a support structure between the die and the substrate. The die may comprise a chip set, a processor or some other integrated circuit.

To determine the force being exerted on a package (die and substrate), a force measurement die 202 in FIG. 2 is substituted in place of a die to emulate a die in a standard “package.” The force measurement die 202 comprises a transducer. The transducer could be of equivalent size similar to the die size and could also be much smaller to accommodate multiple transducers. The force measurement die 202 is preferably shaped with exactly the same dimension and size as a die to be emulated. In one embodiment, the force measurement die 202 is placed and attached (e.g., glued) onto a support structure 204, which is placed and attached (e.g., glued) onto the substrate 208. Like a real package, the substrate 208 is placed on the test socket 210.

A force is applied to test the package (die 202, support structure 204, substrate 208) either on a Tester set up or a System Level Test (SLT) setup. A Tester setup can be different due to test time, which is in seconds, whereas a System Level Test is in minutes. Also, force on Test Contactors used on Testers could be higher as compared to on a System Level Test. The force measurement die 202 is configured to precisely measure an amount of force applied on the die 202 and package (die 202, support structure 204 and substrate 208) by the thermal head 102 and shaft 104. The force measurement die 106 may be coupled to a display 226 or some other device configured to show an amount of measured force to a user. The system 200 allows a user to precisely define the force needed to test a package with minimum pressure on a die.

In one embodiment, the pressure applied to a die in a standard package should be much lower than the pressure applied to the substrate because of the sensitivity of the silicon and C4 solder bumps on the die. Knowing the force on the die based on a specification, one can determine exactly how much force is being applied on the die and on package using the system 200 of FIG. 2. The specification may relate to solder balls for C4 bumps or just solder balls on BGA substrates. C4 solder bumps comprise a certain tin/lead composition, and it is undesirable for them to compress as they are brittle and could damage electrical contacts and also crack the silicon die.

The system 200 may be specifically designed or adapted to precisely measure a desired force on each die and/or package to be tested, such as a Chip Scale (Chip scale packages considered below 0.8 mm pitch, which means the distance between two solder bumps), Ball Grid Arrays, Land Grid Arrays, Micro Organic Pin Grid Arrays and Std Pin Grid Arrays (the distance between adjacent balls may be 0.5, 0.65, 0.8, 1.00, 1.27 mm, and for pin grid arrays it may be of 1 mm and 1.27 mm pitch) for both ceramic and organic substrates. Different dies and packages have different sizes and dimensions. In order to adapt this measuring system 200 and method for various substrates, a customized system may be set up for each of these specific substrate configurations.

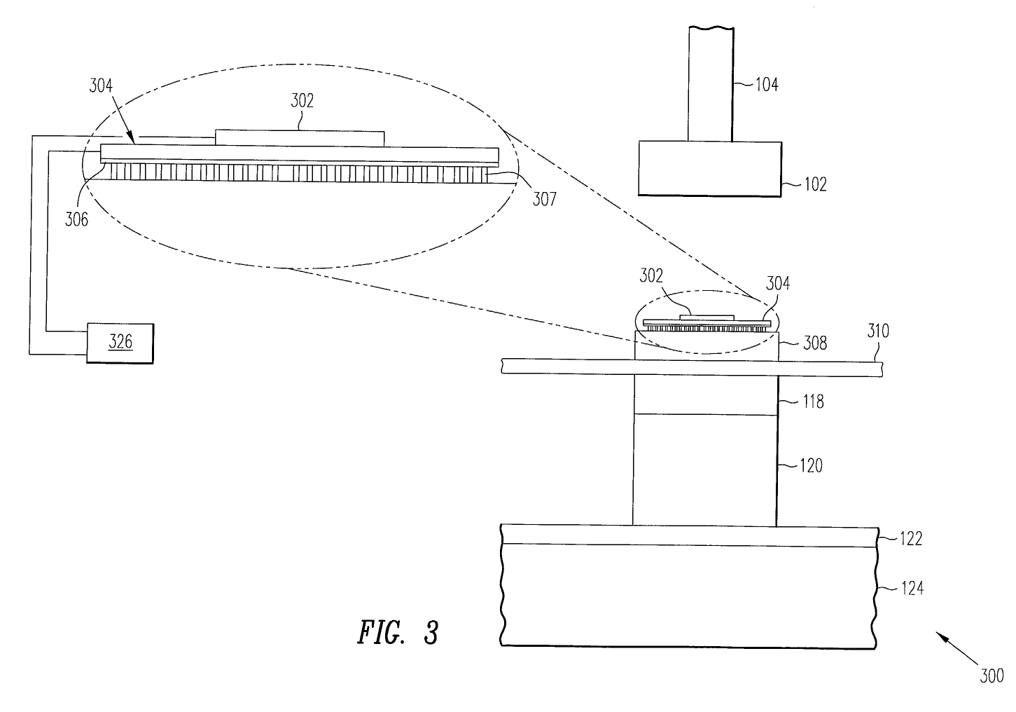

FIG. 3 illustrates one embodiment of a system 300 configured to measure force applied to a force measurement die or device die 302 on a force measurement package 304 and a modified thin substrate 306. The system 300 comprises a thermal head 102, a shaft 104, a force measurement die or device die 302, a force measurement package 304, a substrate 306, a socket 308, a printed circuit board 310, a plastic insulator 118, a support structure 120, a sub-plate 122 and a base plate 124. The system 300 may comprise other components in addition to or instead of the components shown in FIG. 3.

The substrate 306 in FIG. 3 may be organic or ceramic. The support structure 120, sub-plate 122 and base plate 124 may be made of aluminum or some other suitable material.

In one embodiment, a standard “package” (not shown) may comprise a die on a substrate. The die may comprise a chip set, a processor or some other integrated circuit.

Modifying a production unit, i.e., die and substrate, to accommodate a force measurement system 300 involves placing and attaching (e.g., by glue) a force measurement die 302 on top of a force measurement package 304, which is placed and attached (e.g., by glue) to a modified thinner substrate 306. The force measurement die 302 basically comprises a transducer of the same size and width as that of a silicon die, which actually is placed on a package 304. By having the transducer in place of the die, one can measure the pressure on a die.

The thickness of the force measurement package 304 and modified thinner substrate 306 should be the same as an original production substrate (not shown). Thus, the force measurement package 304 and modified thinner substrate 306 may be placed on a production setup, as shown in FIG. 3, and measure the force applied when all the pins 307 of the substrate 306 make contact with the socket (and thereafter on a real package) and verify thermal performance based on force measure data. If a transducer is placed, it should match the die/substrate thickness in order to emulate the actual die/substrate for force calculation.

Thermal performance is required because between the die and heat sink, there is a thermal interface material used which transfers the heat from the die to the heat sink. The interface material acts as a thermal conductor for heat transfer. The interface material used requires a certain amount of pressure/deflection in order to have optimum performance without leaving residues or fibers split apart due to higher force. This is why a minimum but good thermal contact is desired.

The force measurement die 302 and/or the force measurement package 304 may be coupled to a display 326 or some other device configured to show an amount of measured force to a user. A digital readout is available which shows the force being applied on to the die 302 and substrate 304, 306.

The modified unit (force measurement die 302, force measurement package 304, substrate 306) becomes a part of the testing tool or system in place of an actual die/substrate, which may then become the standard material for force calculation each time it is needed. The modified unit may be kept for bench marking prior to production setup. The transducer 302 on the substrate 306 is then kept as the control units, which reflect an actual die/substrate for force calculation. The transducer 302 and actual die/substrate are both of the same size and thickness. The system 300 allows for defining force used in a manufacturing test environment as well as for system level testing (SLT).

The above-described embodiments of the present invention are merely meant to be illustrative and not limiting. Various changes and modifications may be made without departing from the invention in its broader aspects. The appended claims encompass such changes and modifications within the spirit and scope of the invention.

What is claimed is:

1. A test package comprising:
a transducer configured to measure an amount of force applied to the transducer, the transducer being attached to a support structure, which is attached to a substrate, the transducer being shaped and sized to emulate a die to be tested.

2. The package of claim 1, wherein the die to be tested comprises a chip set.

3. The package of claim 1, wherein the die to be tested comprises a processor.

4. The package of claim 1, wherein the die to be tested comprises an integrated circuit.

5. The package of claim 1, wherein the die to be tested has a force sensitivity specification based on solder balls on the die.

6. The package of claim 1, wherein the die to be tested has a force sensitivity specification based on C4 bumps on the die.

7. The package of claim 1, wherein the support structure and the substrate are attached with C4 solder bumps.

8. The package of claim 1, wherein the substrate is organic.

9. The package of claim 1, wherein the substrate is ceramic.

10. The package of claim 1, wherein at least one surface of the substrate has a plurality of pins.

11. The package of claim 1, wherein at least one surface of the substrate has a plurality of solder balls.

12. The package of claim 1, wherein the substrate is configured to be placed on a socket, which is configured to be placed on a circuit board.

13. The package of claim 1, wherein the substrate is configured to be attached to a socket via a plurality of pins.

14. The package of claim 1, further comprising a lid over the transducer and support structure, wherein the force is applied to an outer surface of the lid.

15. The package of claim 1, wherein the force is applied by a thermal head.

16. The package of claim 1, wherein the package is configured to be used in a tester setup.

17. The package of claim 1, wherein the package is configured to be used in a System Level Test (SLT) setup.

18. The package of claim 1, further comprising a display coupled to the transducer, the display configured to display an amount of force applied to the transducer.

19. The package of claim 1, being configured to measure force on Chip Scale.

20. The package of claim 1, being configured to measure force on a Ball Grid Array.

21. The package of claim 1, being configured to measure force on a Land Grid Array.

22. The package of claim 1, being configured to measure force on a Micro Organic Pin Grid Array.

23. The package of claim 1, being configured to measure force on a Standard Pin Grid Array.

24. A system configured to measure force applied to a device, the system comprising:
a means for applying a downward force on a device; and
a device comprising a transducer configured to measure an amount of force applied by the force applying means to the device, the transducer being attached to a support structure, which is attached to a substrate, the transducer being shaped to emulate a die.

25. The system of claim 24, wherein the force applying means comprises a thermal head.

26. The system of claim 24, further comprising:
a socket configured to support the substrate;
a printed circuit board configured to support the socket;
a plastic insulator configured to support the circuit board;
a support structure configured to support the plastic insulator; and
a sub-plate and a base plate configured to support the support structure.

27. The system of claim 24, further comprising a display coupled to the transducer, the display configured to display an amount of force applied to a component on the circuit board.

28. A test package comprising:
a transducer configured to measure an amount of force applied to the transducer, the transducer being attached to a force measurement package, which is attached to a substrate, the transducer being shaped and sized to emulate a die to be tested.

29. The test package of claim 28, wherein the substrate is thinner than a production substrate upon which an actual die will be attached.

30. A method of testing a device, the method comprising:
measuring an amount of force applied to a transducer that is shaped and sized to emulate a die on a substrate;
verifying an amount of desired force for optimal thermal performance and a socket-per-pin force specification; and
setting the verified amount of force to be used in a die and substrate production process.
